(19) United States
(12) Patent Application Publication
(10) Pub. No.: US 2012/0273023 A1
(43) Pub. Date: Nov. 1, 2012

(54) COLLAPSIBLE REFLECTOR FOR SOLAR PANEL

(76) Inventor: Jonathan ELY, Lakewood, NJ (US)

(21) Appl. No.: 13/096,576

(22) Filed: Apr. 28, 2011

(51) Int. Cl. H01L 31/052

(52) U.S. Cl. 136/246

(57) ABSTRACT

A reflector apparatus that includes reflector slats that reflect light from the sun onto solar panels, solar heaters, solar generators or the like is described. The reflector slats may be supported on upright poles and may be tiltable to reflect or to focus light onto the solar panels based on a sun tracker or a heat sensor output. In a default or collapsed position, based on readings from a wind sensor, the reflector slats are moved down on the poles to avoid risk of being damaged by heavy winds or other weather conditions

### FIELD OF THE INVENTION

The present invention is in the field of reflectors for providing light to solar panels for generating solar energy, solar heaters and the like.

### BACKGROUND OF THE INVENTION

In recent years, renewable energy such a solar energy has been growing in popularity and importance in the United States and around the world. Many residential and commercial buildings now have solar panels, solar water heaters and the like on roofs, terraces or elsewhere and solar heat generators that raise the temperature of water to produce steam and make use of the steam to drive turbines are also well known.

Solar panels are limited by the amount of sunlight that is incident on their surface. Reflectors that track the sun and focus sunlight on a central turbine or a steam generator have been used for years and solar energy farms are well known. Typically, such arrangements are massive in scale and require permanently installed apparatuses that stand up to the elements, including heavy winds or even rainstorms, snowstorms and tornados.

However, solar panels arranged on a roof of a private residence or a small or midsize building or the like could also benefit from a reflector system that would add to the amount of energy received, provided that the reflector system is not destroyed or at least blown over by wind or storms or damaged by heavy precipitation or the like.

### SUMMARY OF THE INVENTION

Described herein is a reflector apparatus that is designed to reflect light from the sun onto solar panels, solar heaters that heat water to be used as hot water in a building, solar steam generators and the like to increase the amount of incident light and/or heat at the solar panels. Reflector apparatus includes reflector slats supported by two or more supporting upright columns or poles that stand approximately perpendicular to the roof or approximately perpendicular to the plane in which the solar panels lie. One or more sun tracker sensors or heat sensors may be provided and the reflector slats of the reflector apparatus may be tilted based on the position of the sun detected so as to achieve maximum reflected light onto the solar panels.

The reflector apparatus may be conceptualized as being analogous to a venetian blind in that the reflector slats may be tiltable and may be collapsible while the poles at the sides remain in a fixed position. To minimize the risk of damage from the elements, such as damage from the force of the wind, the reflector slats may be brought down to a collapsed position with the supporting poles remaining standing. A cover may be provided above the reflector slats, which may also collapse onto the reflector slat in the collapsed position so as to protect the reflector slats. Alternatively, the cover may remain fixed at a topmost position supported by holes. The tilting of the reflector slats to achieve maximum radiation onto the solar panels based on the tracking of the sun or based on the heat sensed at the solar panels may be accomplished automatically using a controller, which may be positioned at a base of the reflector apparatus. Also, bringing the reflector slats to the collapsed position, as well as deploying the reflector slats in the deployed position along the length of the supporting poles may be also controlled automatically according to whether the wind detected is below an acceptable safe threshold level and to whether a minimum amount of heat or radiation is detected. The collapsed position may be the default position for the reflector slats so as to protect the reflector apparatus and prioritize safety.

Accordingly, the present disclosure provides a solar panel installation, which includes a solar panel arrangement mountable on one or more locations on the roof surface with a solar reflector apparatus disposed to the side of the solar panel arrangements to reflect sunrays to the solar panels. A collapsing mechanism is coupled to the reflective members and is configured to collapse the reflective members downward along a height wise extended direction upon sensing a wind force greater than a predetermined amount. As noted, the solar reflector apparatus can be in the shape of a plurality of slats arranged as in a venetian blind with the venetian blind slats collapsing entirely downward, under high wind conditions and being pulled upwards otherwise (compressed to the typical operation of venetian blinds). The solar reflector apparatus can also pivot the individual slats or the entire installation can be rotated about the vertical axis or pivoted about a horizontal axis at the bottom of the solar reflector apparatus. The slats can be supported on left and right, spacably arranged upright supports, to electronically control the solar panel installation. A controller is included to receive an input signal as representative of the environmental parameters, for example, a solar position sensor, a wind sensor, a temperature sensor and the like. The wind sensor may be a piezo electric device. The individual slats can have flat o convex reflecting surfaces.

In accordance with another embodiment, the reflective member can be comprised of a myler sheath supported between the uprights and having formed therein a plurality of cuts that allow the cut panels to create openings for the wind to pass through without collapsing or breaking the solar installation. When the solar panel arrangement are disposed on opposite sides of the pitched roof, the sun reflector apparatus can be provided for each such solar panel and the controller may be programmed to constantly adjust the position of the reflective slats to optimize the amount of sun that reaches the panels.

Other features and advantages of the present invention will become apparent from the following description of the invention which refers to the accompanying drawings.

### BRIEF DESCRIPTION OF THE DRAWINGS

FIG. 1 is a schematic side view of a pitched roof with solar panels and an example of a reflector apparatus according to an aspect of the present invention.

FIG. 2 is a schematic perspective view of an example of the reflector apparatus according to an aspect of the present invention.

FIG. 3 is a schematic front view of an example of the reflector apparatus in a retracted state according to an aspect of the present invention.

FIG. 4 is a schematic diagram illustrating an example of a control system for the reflector apparatus according to an aspect of the present invention, including a section of the supporting poles of the reflector apparatus.

FIG. 5 is a schematic perspective view of a detail of a pole provided as an example for the reflector apparatus according to an aspect of the present invention.

FIG. 6 is a schematic perspective view of an example of the reflector apparatus in a carousel mode according to an aspect of the present invention.

FIG. 7 is a schematic view of a sliding box inside the channel of a supporting pole of the reflector apparatus according to an aspect of the present invention.

FIG. 8 is a schematic illustration of an example of a tilting actuator inside a channel of a supporting pole of the reflector apparatus according to an aspect of the present invention.

FIGS. 9A and 9B are schematic side views of a concave reflector slat and a flat reflector slat, respectively, of the reflector apparatus according to an aspect of the present invention.

FIG. 10 is a schematic illustration of another embodiment using a wind impervious single reflective sheath panel.

### DETAILED DESCRIPTION OF EMBODIMENTS OF THE INVENTION

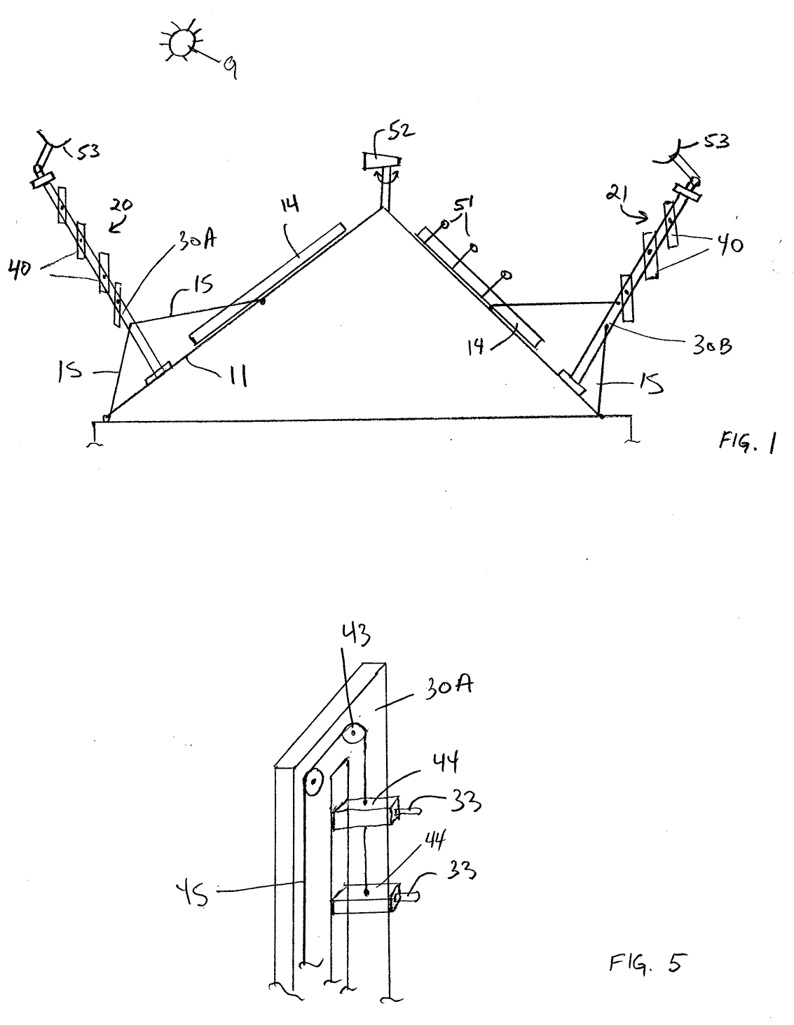

FIG. 1 illustrates an example of a reflector apparatus 20 of the invention as well as a second reflector apparatus 21. In a typical pitched roof 11 arrangement, solar panels would be arranged on both sides of the pitched roof 11, as shown in FIG. 1. As the sun moves through its daily course across the sky, fixedly stationed solar panels 14 would receive varying amounts of radiation. Reflector apparatus 20 and reflector apparatus 21 are illustrated as positioned on opposed sides of the pitched roof 11 and a number of reflector slats 40 positioned in the reflector apparatus 20 reflect light from the sun onto solar panels 14. Even when the sun is directly overhead much of the radiation would miss solar panels 14 and thus reflector slats 40 of reflector apparatus 20 are positioned to reflect additional light onto solar panels 14. It would be understood that reflector apparatus 20 can be used individually of reflector apparatus 21 and that additional reflector apparatuses may be positioned at various portions of the roof depending on the shape of the roof, its size and other such considerations.

Reflector apparatus 20 and reflector apparatus 21 are shown as positioned approximately perpendicular to the plane along which solar panels 14 are positioned. Thus, reflector apparatus 20 and reflector apparatus 21 may, but need not, be stationed perpendicular with respect to the ground or with respect to a flat roof. It would be understood further that the term “approximately perpendicular” can be anywhere from 60° to 130°. However reflector apparatus 20 and reflector apparatus 21 may be positioned perpendicular to the ground or to a flat roof and in fact since reflector slats 40 may be provided as tilting depending on the position of the sun, such positioning of reflector apparatus 20 and reflector apparatus 21 may be more convenient depending on the roof without sacrificing undue radiation potential. FIG. 1 also shows tethers 15 that moor the reflector apparatus 20 to the roof 11. One, two or more tethers 15 can be used. Instead of or in addition to tethers 15, supporting rods can also be used to moor the reflector apparatus 20 to the roof.

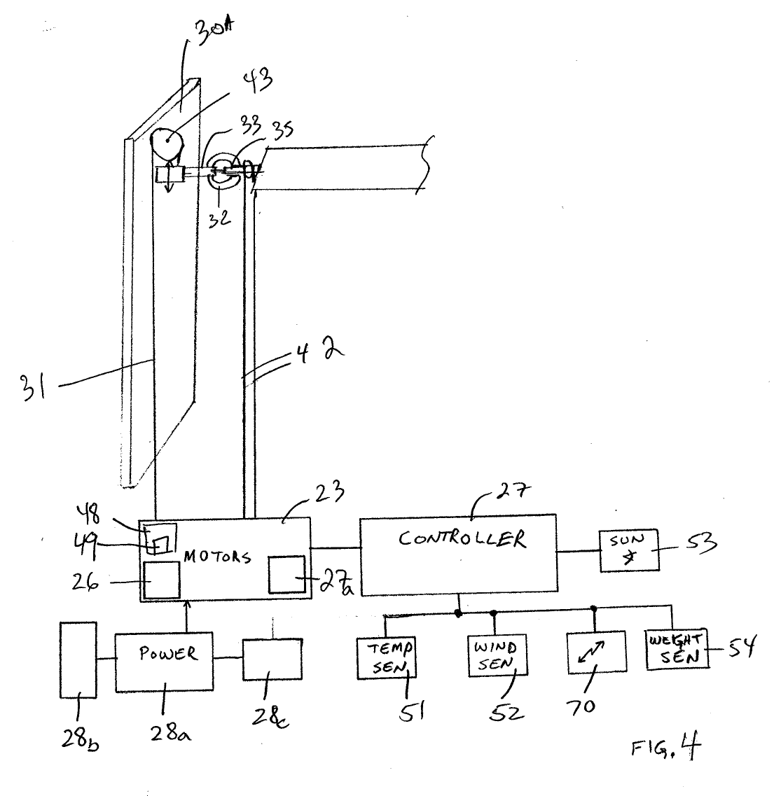

FIG. 1 also illustrates sun tracker sensor 53 designed to sense the position of the sun in real time and to transmit the position of the sun to controller 27 illustrated in FIG. 4. Sun tracker 53 may be a heat sensor that searches for the angle at which it is hottest based on where most light is received and thus detects the position of the sun. Sun tracker 53 may also be configured as a radiation sensor that detects an amount of electromagnetic radiation or a frequency bandwidth thereof, and thus tracks the position of the sun based on where the most radiation is received. Sun tracker sensor 53 is illustrated as positioned at a top portion of the reflector apparatus 20 and reflector apparatus 21. However, it would be understood that one such sun tracker 53 may be sufficient. Sun tracker sensor 53 may be positioned at other portions of the reflector apparatus, for example at the base 23 of the reflector apparatus 20 at a side of pole 30A or pole 30B of reflector apparatus 20 or may be positioned as a separate module on other portions of the roof 11. The poles 30A and 30B can be braced to each other at their top ends by brace member 7.

Controller 27 shown in FIG. 4 may also include a minimum temperature threshold and when controller 27 receives a temperature reading from sun tracker sensor 53 indicating that the current maximum temperature at which the sun is tracked is below this minimum temperature threshold, then controller 27 could send reflector apparatus 20 and reflector apparatus 21 commands to move to the retracted position, as illustrated in FIG. 3.

FIG. 1 also shows wind sensor 52 that senses a direction and a force of the wind in real time and transmits this information to controller 27 illustrated in FIG. 4. If the wind force exceeds a threshold level that is deemed dangerous or potentially dangerous to reflector apparatus 20 or reflector apparatus 21 or to its stability, or deleterious to its proper functioning, controller 27 commands reflector apparatus 20 to go into a retracted mode, as illustrated in FIG. 3.

Wind sensor 52 may be designed to detect the direction from which the strongest wind force is received and to determine the strength of the wind from the strongest direction. Thus, wind sensor may first determine the direction of the strongest wind and then determines its strength. Alternatively, wind sensor 52 may continually take readings from each major direction.

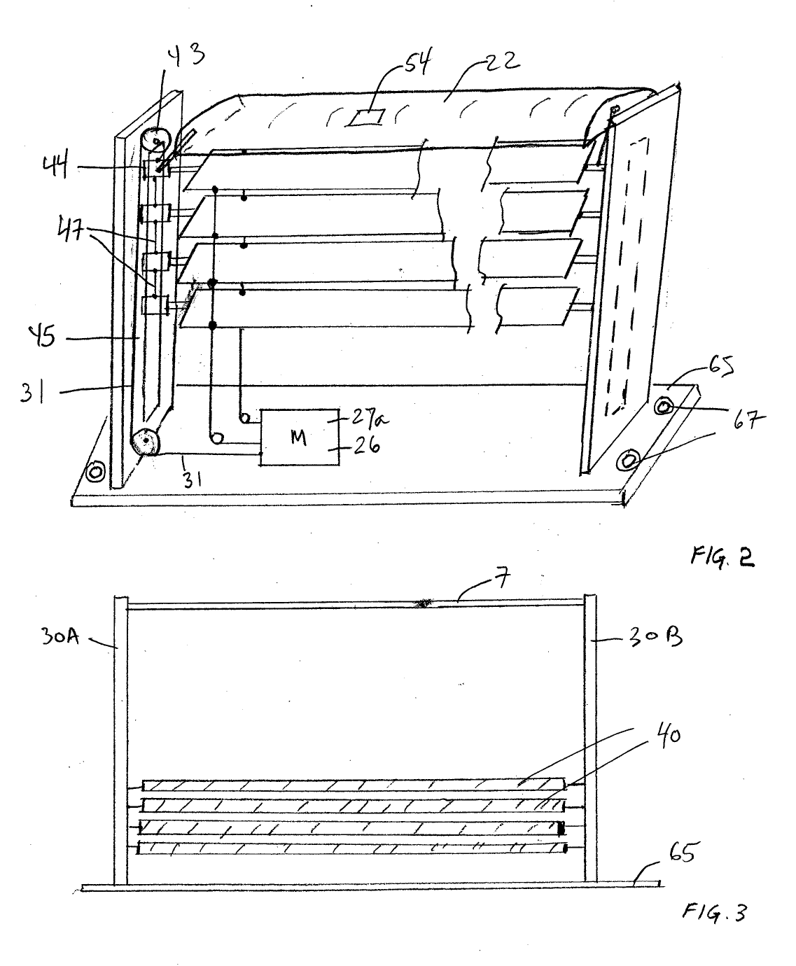

Weight sensor 54 which sits atop the apparatus (FIG. 2) may be included as shown in FIG. 4 to provide the controller 27 an indication when too much weight bears on the apparatus 20/21, for example, during the winter when too much snow may accumulate thereon, to protect it from breakage by commanding it to move to the retracted position.

According to a further embodiment of the invention, controller or CPU 27 may be programmed with several wind force thresholds depending on the direction of the wind. Thus, wind that hits the reflector apparatus 20 head on, that is from the front or from the back may be deemed to pose more risk because the greater surface area of the reflector apparatus 20 provides greater resistance. Therefore, controller 27 may provide a command to enter a collapse position for the reflector apparatus 20 at a lower threshold than wind that impacts reflector apparatus from a side, for example, from the direction of view shown in FIG. 1, since from this angle the reflector apparatus 20 would make a much thinner target and thus provide much less resistance to the wind force, and it would therefore encounter less total wind power. In between the threshold wind danger value for wind coming from a head on direction (e.g. from the view illustrated in FIG. 2) and the threshold wind danger value for wind coming from a side direction (as illustrated, for example in FIG. 1) a range of other thresholds can be set in controller 27, so that retractor position for reflector apparatus 20 is only initiated when wind from at least one wind direction meets or exceeds the respective threshold for wind danger.

Temperature sensors 51 may also be provided on or between or near the solar panels 14 and thus the tilting of the reflector slats 40 may be controlled based on the temperature reading detected at temperature sensor 51. Thus, the reflector slats 41 may be tilted to achieve the maximum temperature reading at temperature sensor 51. It would be understood that one or more temperature sensors 51 may be provided and that temperature sensor 51 at the reflector slats 40 may be provided in addition to sun tracker 53 provided on or at the reflector apparatus 20 and/or reflector apparatus 21. Alternatively, the sensors 51 may be configured as electrical output sensors, which issue a signal indicative of the voltage or power output level of the solar panel coupled to the given sensor 51.

As discussed, when a wind force exceeding a certain threshold, or a certain threshold from a particular direction, is detected by wind sensor 52, controller 27 provides instructions for entering a retracted mode illustrated in FIG. 3. For example, controller 27 may comprise a computer, a chip or other electrical circuits to embody the logic described herein. Controller 27 may instruct vertical lift motor 26 located inside movement housing 23 to tug on string 41 supported on pulley 43 that will cause sliding boxes 44 to slide up inside channel 45.

As illustrated in FIG. 5, sliding boxes 44 may move inside a groove or channel 45 located on the proximal side of pole or upright panel 30A. Sliding boxes 44 may also have wheels (not shown) located inside the channel 45 to facilitate movement up and down inside channel 45. Attached to sliding boxes 44 is shaft 33, and each reflector slat 40 is connected to shaft 33 which supports it on its sliding box 44. In addition, controller 27 may command a latching mechanism 48 that includes latch 49 that latches around a string 41 when the desired height is reached for the reflector slats 40 in the deployed position of the reflector slats 40.

When controller 27 determines that a maximum threshold for wind conditions has been reached, it signals latching mechanism 48, including latch 49 to release the string, causing the reflector slats 40 to descend as the sliding boxes 44 roll down or slide down in channel 45. In addition, when the reflector apparatus is not in use, such as at night, as determined by the controller 27 based on the reading from temperature sensor 51 and/or based on a reading from sun tracker 53 that a minimum heat level or radiation level is not reached, controller 27 will enter the retracted mode as illustrated in FIG. 3. According to a preferred embodiment, retracted mode illustrated in FIG. 3 may be initiated as a default mode, such that the deployed mode for the reflector slats 40 as illustrated in FIG. 2 is only initiated when both a minimum temperature level or radiation level is detected by temperature sensor 51 and/or sun tracker 53 and a maximum wind force level is not detected by wind sensor 52.

Also illustrated in FIG. 2 is a canopy-shaped, wide cover 22 that covers the reflector slats 40 and all or much of the reflector apparatus base 65, or at least covers the portion of the base that includes the movement housing 21 in the retracted position, protecting same against settling dust, rain and the like, in the stowed/retracted position. The cover 22 is physically attached to the sliding boxes 44 of the uppermost slot, as shown in FIG. 2 and moves up/down therewith.

Reflector slats 40 may also be configured to tilt (together or individually) to achieve the maximum radiation directed at the solar panels 14. As shown in FIG. 4, inner shaft 35 can rotate inside bushing 32 to achieve this tilt. As shown in FIG. 4, tilting motor 27a may be commanded by controller 27 to tug on strings 42 attached to the shaft 35 of each of the reflector slats 40. Inner shaft 35 can rotate inside bushing 32 to achieve the tilting of the reflector slat 40 in response to the tugging of the strings 42.

In the alternative, individual motors (not shown) can be provided at each reflector slat position inside pole 30B. FIG. 7 shows pole 30B with channel 45 in which sliding box 44 is positioned. Sliding box 44 includes shaft aperture 37 through which shaft 35 extends. The end of shaft 35 includes x-slot 37 shown in dotted lines. Illustrated in FIG. 8 is actuator 36 provided inside channel 45 of pole 30B. Actuator 36 engages x-slot 35 of shaft 35 when tilting of the reflector slat 40 is desired. Actuator 36 is then rotated by the tilting motor to achieve the degree of rotation desired for reflector slat 40. When the reflector slat 40 is tilted to the desired position, actuator 36 may be retracted away from the end of shaft 33 or may be kept in place so as to maintain reflector slat 40 at its tilted angle. The poles/uprights 30A and 30B are supported on base 65 which can be affixed to the roof by screws or bolts 67.

Actuator 36 as well as actuators for each remaining reflector slats 40 may be controlled to move in unison or may be individually controlled. Thus, actuators such as actuator 36 may be provided for each of the reflector slats 40 of reflector apparatus 20 and may be controlled by a single motor. For example, a rod may extend inside pole 30B and may control all actuators 36 to tilt by a certain amount and may also control all actuators 36 to advance and/or to retract when necessary to engage with x-slots 35. Although shown as x-slots and as x-shaped actuator 36, it would be understood that other such shapes may be provided to achieve temporary locking engagement between the end of shaft 33 and actuator 36. When the shaft 33 is tilted, the reflector slat 40 will tilt with the shaft 33 but bushing 32 will allow for tilting without tilting shaft 33. Alternatively, actuators 36 may be configured on both pole 30A and 30B and may work in unison on both pole 30A and 30B for each reflector slat 40 to achieve tilting. Individual tilt control for each reflective slat 40 can provide the benefit of a finer and more precise focus of the light on the solar panels 14. For example, each slot may be configured to concentrate its light on a particular region of the solar panel.

The default mode in the deployed state for the reflector apparatus 20 is the horizontal position for the reflector slat 40 so as to provide minimum resistance to wind and thus to achieve minimal risk to the reflector apparatus 20 in the deployed state, and to allow rapid collapsing of the slots and to allow the slots to contact and cover each other in the stowed position. Also, in this default deployed horizontal mode, the retracted collapsed mode as illustrated in FIG. 3 is most quickly achieved without damaging or scratching reflector slat 40.

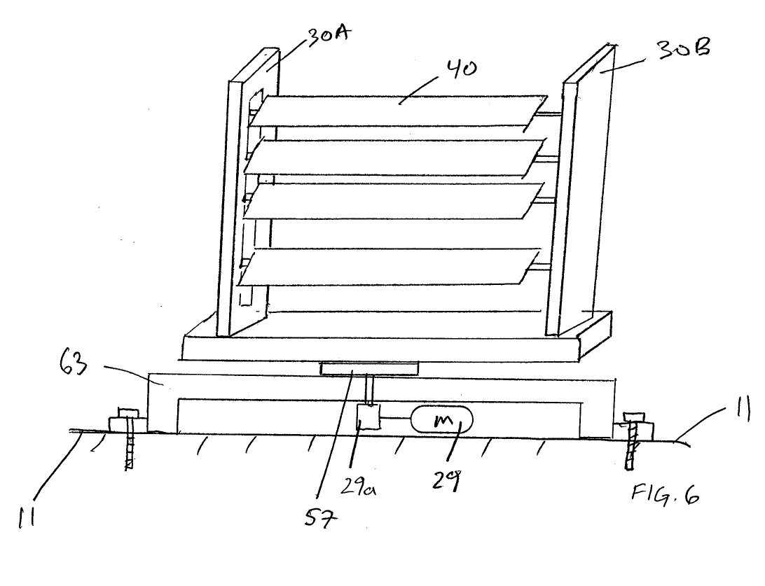

Also shown in FIG. 6 is rotating platform 57 which may be controlled by rotating motor 29, via gear box 29a. Depending on the position of the sun as sensed by sun tracker 53 or by heat sensor 51, it may be advantageous to rotate the entire reflector apparatus 20 on base 63 via carousel 57, along a plane roughly perpendicular to the axis of poles 30A and 30B. In this way, maximum light can be reflected onto the solar panels 14, even when the solar panels 14 are oriented in a north-south direction. The inventor also contemplates mounting the apparatus so that its vertical plane is tiltable toward/away relative to the solar panels, by passing a pivoting axis through the base 65 and pivoting the plane of the uprights 30A, 30B so as to bend toward or away from the panels 14, depending on the position of the Sun 9.

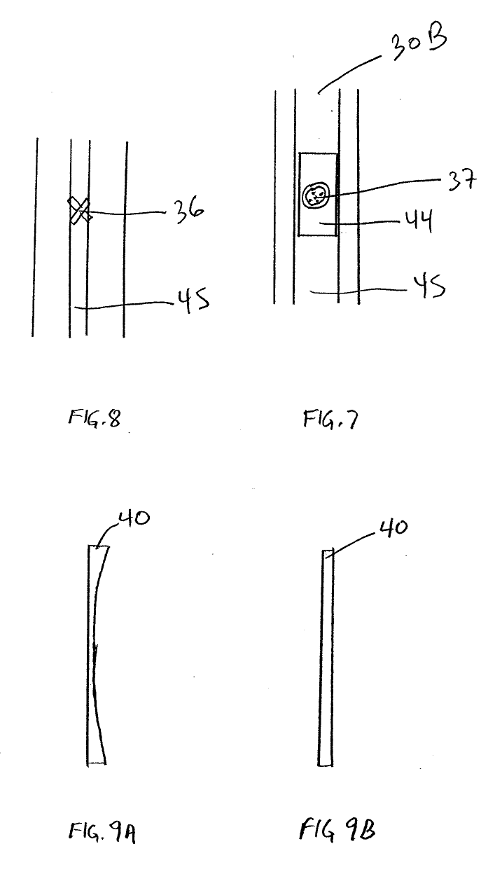

Reflector slats 40 can be flat or concave or slightly concave to achieve a maximum focusing and reflecting of the light. Illustrated in FIG. 9A is a slightly concave reflector slat 40 and illustrated in FIG. 9B is a flat reflector slat 40. Reflector slat 40 shown in FIG. 9A may be designed to focus more of the available radiation onto the solar panel 14.

Reflector slats 40 and poles 30A and 30B may be made of metal, such as aluminum or may be made of coated glass or various types of reflective plastics. A lightweight construction may be achieved by use of light materials, such as aluminum or various types of reflective plastics. For example, highly polished aluminum materials may be used for the reflective slats 40 and they may be provided as a wing type shape.

As illustrated in FIG. 4, the system includes power source 28a for controller 27, vertical lift motor 26, rotating motor 27 and other motors of the reflector apparatus 20. Power supply 28a may be powered by a solar powered panel shown schematically as 28b. A backup power source 28c, e.g., a rechargeable battery, is also contemplated so that, at least on an emergency basis when the retracted position is necessary as dictated by high winds or inactivity, such a retracted state can be achieved even when power 28A fails.

For allowing remote controlling of the CPU 27, wireless remote interface 70 (FIG. 4) allows communication with a remote computer (not shown), through which a user may exercise manual control over all apparatus functions and test modes and set or control its various parameters, as may be needed.

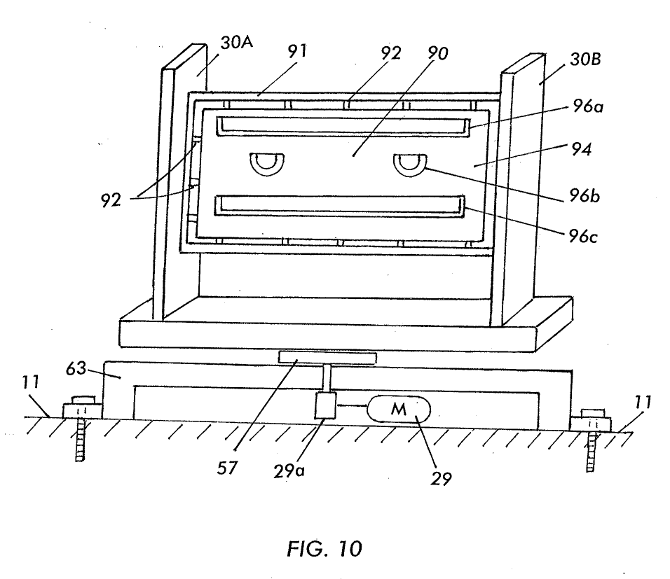

FIG. 10 shows a further embodiment of the invention which is similar to FIG. 6, except for the pivotal slats 40 being replaced by a single panel 90 which utilizes a large myler coated reflective sheet 94. Wind stresses are minimized by providing numerous wind relief cuts in the form of wind relief scallops 96a, 96b, 96c over the entire sheath 94. The sheath 94 is mounted on an upper support bar 91, which similarly to the upper slat in the prior amendment is collapsible to reduce the surface that can be subjected to wind shear forces in the case of extremely high wind conditions.

Directing the sunrays unto the solar panels (which incidentally can be water filled chambers covered by glass (to meet the hot water needs of a home or a business) is accomplished by pivoting and/or rotating the two upright poles 30A and 30B. That is, the element 57 is intended to indicate a support plate that is both rotatable and pivotable in a manner which allows the base, which supports the two uprights 30A and 30B, to rotate or pivot, as needed, to aim the sunshine rays unto the solar panels. Although not previously mentioned, it is implicit in the description of the present and the foregoing embodiments that the temperature sensors 51 can also be utilized by the controller 27 to control the sun directing slats or the sheath 94 away from the solar cells in the event that it is determined that the amount of sun reaching those panels is too high as to interfere with the operation or pose a risk of damage to the solar panels.

In the preceding description, mention was made of the sunray tracker for tracking the position of the sun. However, it is within the ambit of the invention for the controller 27 to be programmed with the positions of the sun, based on the time of day and the date of operation and the particular location at which the solar panel arrangement is installed. For example, if the panel is installed on a house roof in New York City, the installation of the system would include inputting into the controller 27 the precise position and orientation of the solar panels and the reflecting apparatus and then the system could use that information to program and guide, on a daily basis, the precise orientation of the reflecting slats relative to the solar panels, without having to track the positions of the sun. In accordance with one embodiment, during the initial installation, an initialization program or algorithm in the controller 27 would first involve installing on one of the slats a light source and thereafter, the program would automatically search when the light source is aligned with one or more points of the solar panel to determine the physical spacing including distance and angular orientation relative to the solar panels which would be then stored within the controller 27. Thereafter, an internal program would calculate the precise position of the slats for the rest of the year based on the initially set date and the initially set geographic coordinate locations of the system. Alternatively, this information can be done by wireless communication with a remote website and the like.

Although the present invention has been described in relation to particular embodiments thereof, many other variations and modifications and other uses will become apparent to those skilled in the art. It is preferred, therefore, that the present invention be limited not by the specific disclosure herein, but only by the appended claims.

What is claimed is:

1. A solar panel installation, comprising:
a solar panel arrangement mountable at, at least one location on a roof surface;
a solar reflector apparatus disposed in spaced lateral displacement relative to the solar panel arrangement and comprising reflective members configured to direct sunrays unto the solar panel arrangement, the reflecting members being arranged so that they extend generally along a height direction; and
a collapsing mechanism coupled to the reflective members and configured to collapse the reflective members downward along said height direction, upon sensing a wind force greater than a predetermined value.

2. The solar panel installation according to claim 1, wherein said reflecting members comprise an array of venetian-blind style slats arranged spacedly along said height direction.

3. The solar panel installation according to claim 2, wherein each of a plurality of said reflective members is pivotable about a respective axis extending generally perpendicularly to said height direction.

4. The solar panel installation according to claim 3, further including a first and second, spacedly arranged, upright supports, said plurality of reflective members extending generally horizontally between said upright supports.

5. The solar panel installation according to claim 4, further including a base on which the upright supports are anchored.

6. The solar panel installation according to claim 4, wherein said upright supports are rotatable around a height wise extending axis.

7. The solar panel installation according to claim 4, wherein said upright supports are pivotable about a generally horizontally extending axis.

8. The solar panel installation according to claim 1, further comprising a controller for receiving input signals representative of environmental parameters, and a plurality of sensors including a wind sensor for generating said input signals.

9. The solar panel installation according to claim 8, further including at least one of a sun position sensor, and a solar panel electrical output sensor.

10. The solar panel installation according to claim 1, further including at least one motor for controlling the collapsing of the reflective members.

11. The solar panel installation according to claim 5, wherein said at least one motor is also configured to cause said reflective members to effect one of a pivoting movement of the reflecting members about a height wise axis or the pivoting of said reflective member to an axis that extends through said base.

12. The solar panel installation according to claim 1, wherein the collapsing mechanism comprises a wind force sensor and control that collapses the reflective members to a bottom position upon detecting a wind stronger than a predetermined value and deploys the reflective members by pulling them upward to arrange them in spaced relation to one another when the wind force is below said determined value.

13. The solar panel installation according to claim 12, wherein the wind force sensor includes a piezoelectric device, which senses the force of the wind impinging on a surface thereof.

14. The solar panel installation according to claim 1, wherein the solar panel arrangement comprises a first panel arrangement mounted on a roof surface extending at the first angle to the horizontal, and a second solar panel arrangement extending on a second roof portion extending at a different angle relative to the horizontal and including first and second solar reflection arrangements disposed respectively relative to the first and second solar panel arrangements.

15. The solar panel installation according to claim 1, wherein a plurality of the reflective members have a respective convex reflecting surface.

16. The solar panel installation according to claim 1, wherein the reflecting members comprise a single myler sheath with a plurality of cuts through the sheath to alleviate wind sheer forces.

17. The solar panel installation according to claim 1, further including a cover member located above an upper most one of the reflective members and slidable up and down along said height wise direction with said reflective members.
